(19) United States
(12) Patent Application Publication
(10) Pub. No.: US 2008/0020935 A1
(43) Pub. Date: Jan. 24, 2008

(54) Phonon maser

(76) Inventor: Boris Volfson, Huntington, IN (US)

Correspondence Address: BORIS VOLFSON, APT. 3046, 5707 W. MAPLE GROVE RD., HUNTINGTON, IN, 46750, US

(21) Appl. No.: 11/599,583

(22) Filed: Nov. 14, 2006

Related U.S. Application Data
(60) Provisional application No. 60/832,334, filed on Jul. 22, 2006.

(51) Int. Cl. H01S 3/09; H01S 1/06; H03B 17/00

(52) U.S. Cl. 505/180; 331/94.1

(57) ABSTRACT

A phonon maser is comprised of a resonant cavity, a superconductive gain medium, and pumping means. The resonant cavity is comprised of highly reflective means and partially reflective means. The superconductive gain medium is an elongated superconductor, which may be a crystalline high-temperature ceramic superconductor or a single-crystal superconductor. The pumping means provide electromagnetic energy for the superconductive gain medium in order to form and then excite Cooper pairs. Trapped in the resonant cavity and amplified by the population inversion, the resonating bundles of superposed free phonons eventually break through the partially reflective means and enter the vacuum of space in a collimated, coherent, and all-penetrating beam of bundles of superposed guest phonons. This beam changes properties of the ambient space, including its gravitational energy.

### TECHNICAL FIELD

This invention relates to methods and devices for signal amplification by stimulated emission of radiation, specifically to methods and devices for vibration energy amplification by stimulated emission of radiation.

### BACKGROUND OF THE INVENTION

The possibility of projecting a coherent beam of high energy at great distances has interested many physicists. The first step toward this goal was understanding the physical nature of the vacuum.

In 1887, the Michelson-Morley experiment showed that the Earth's motion does not cause winds in a light-carrying medium in space. For some time, this result was misinterpreted as indicating that the vacuum of space is absolutely empty. In December 1900, Max Plank published a paper that outlined the law of black-body radiation, thus giving birth to quantum mechanics.

In 1916, building upon this law, Albert Einstein created the foundation for the invention of both the maser and, later, the laser with his concepts of spontaneous and induced emissions. In 1911, Heike Kamerlingh-Onnes chilled mercury to superlow temperatures and found that electrical resistance vanished at 4.2 K. He called this stange physical state superconductivity winning the 1913 Nobel Prize in physics for this work.

In 1932, a series of experiments performed by Carl D. Anderson proved that absorption of a Gamma-ray energy quantum of 1.02 million electron volts (1.02 MeV) in any point of space makes a free electron and positron pair to appear. When such a pair of particles disappears in any point of space, there are at least two quanta emitted, with a total energy of 1.02 MeV. This means that radiation turns into electrons and positrons, and that electrons and positrons, in-turn, annihilate into energy (radiation).

In a July, 1940, interview with The New York Times, Nikola Tesla claimed to have invented a device that produced a “tremendous repelling force” by catapulting “microscopic electrical particles” into space. This “teleforce” beam, per Tesla, would be capable of “eliminating high vacuum”.

In the late 1940s, H. B. G. Casimir proved that the vacuum is neither particle- nor field-free. It is a source of zero-point-fluctuation (ZPF) of fields such as the vacuum gravitational field. ZPF fields lead to real, measurable physical consequences such as the Casimir force.

In 1953, Charles H. Townes, James P. Gordon and Herbert J. Zeiger produced the first maser, a predecessor to the laser. The maser, unlike the laser, projected microwave (rather than optical) radiation. In 1957, Charles Townes and Arthur Leonard Schawlow of Bell Labs, simultaneously with Gordon Gould, proposed the idea of an optical maser, later called laser. This invention established a new field in physics and industry. However, applications of lasers, especially in the Earth's atmosphere, are limited by beam dispersion due to collisions of photons with the molecules comprising air. Furthermore, the laser and maser provide only light and/or heat. Thus, the applications of these two devices are limited to these two effects.

In his Nobel Prize lecture, Townes anticipated that phonons could also be mased. In the last chapter of this work, this chapter titled “The Phonon Maser”, Townes writes: “Acoustic waves follow equations that are of the same general form as the equations of light and manifest many of the same phenomena. An acoustic wave can produce an atomic or molecular excitation, or receive energy from it by either spontaneous or stimulated emission. Hence, one may expect maser action for acoustic waves if a system can be found in which molecules are sufficiently coupled to an acoustic field and appropriate excitation can be found to find the threshold condition”. Production of Coherent Radiation by Atoms and Molecules. Charles H. Townes. Nobel Lecture. Dec. 11, 1964.

Also in 1957, Bardeen, Cooper and Schrieffer published a paper on their quantum-mechanical theory of how, at very low temperatures, the formation of electrons into pairs (hence Cooper pairs) permits superconductivity in some materials (“Microscopic Theory of Superconductivity”, J. Bardeen, L. N. Cooper and J. R. Schrieffer, Physical Review 106, Issue 1-1 Apr. 1957, pp. 162-164). For this new theory, its authors were awarded the 1972 Nobel Prize in physics.

In the early 1970's, Menahem Simhony hypothesized that the vacuum of space is permeated by a three-dimensional crystal lattice. Earlier in his career, Simhony assumed that this crystal lattice included (real) electrons and holes. Later on, Simhony thought that (real) positrons were also present in the crystal vacuum lattice. (“Invitation to the Natural Physics of Matter Space and Radiation”, M Simhony, 1994 published by World Scientific Publishing Co. Pte. Ltd. ISBN 981-02-1649-1). According to Simhony, a cubic millimeter of vacuum lattice contains 6×10³³ electron-positron pairs with a combined binding energy of 27×10¹⁵ kW. Simhony calculated the binding energy of each cell to be 1.02 MeV. By analogy with ionic alkali halide salts (sodium chloride in particular), the dimension of each side of the unit cube comprising 2 electrons and 2 positrons of the face-centered cubic lattice at rest has a lattice constant of 4.4 (±0.5)*10⁻¹⁵ m.

The majority of scientists, however, believe that most of the vacuum-permeating positrons and electrons are not real (massive) but virtual (pure energy). The virtual particles are merely fluctuations of vacuum energy. To these scientists, the Casimir effect and, possibly, gravity and repulsion, are proofs of the existence of this energy. Unlike Simhony, these scientists believe that the density of real electrons and positrons in the vacuum is very insignificant. A manifestation of the relative sparsity of these electrons and positrons is in the small positive value of the cosmological constant.

In the 1991 U.S. Patent Application #5012302, Herb Goronkin disclosed a phonon generator that promotes the formation of Cooper pairs in a superlattice. The particulars of the disclosed device permit Cooper pairs to form and exist at temperatures that are typically too high for superconductivity.

In the early 1990s, Ning Li and D. G. Torr described a method and means for converting an electromagnetic field into a gravitomagnetic field. Li and Torr suggested that, under the proper conditions, the minuscule force fields of superconducting atoms can “couple”, compounding in strength to the point where they can produce a small repulsive force (“Effects of a Gravitomagnetic Field on Pure Superconductors”, N. Li and D. G. Torr, Physical Review D, Volume 43, Page 457, 3 pages, 15 Jan. 1991).

A series of experiments, performed in the early 1990's by Evgeny Podkletnov, reportedly resulted in a reduction of the weight of objects placed above a levitating, rotating superconductive disk subjected to high frequency magnetic fields. (“Weak Gravitational Shielding Properties of Composite Bulk YBa₂Cu₃3O(7-x) Superconductor Below 70K Under E. M. Field”, E. Podkletnov, LANL database number cond-mat/9701074, v. 3, 10 pages, 16 Sep. 1997). The drawback of the technology described in Podkletnov's above-mentioned paper is the weakness of the resulting effect. Even though Podkletnov has reported 0.3%-to-2.1% weight reduction with the device described in the above-mentioned 1997 paper, many scientists point to a likelihood of error in Podkletnov's measurements.

In 2003, Randall Peters hypothesized the possibility of creating a phonon maser based on “mechanical oscillations by stimulation of excited states”. Peters suggested that the acoustic memory experiments of 2002, and the optically driven pendulum experiments of 1996, would lead to a practical phonon maser. Per Peters, the mechanism of this maser would depend on the metastability of defect-structure organization (“Friction as Basis for a Phonon Maser”, Randall D. Peters, arXiv:physics/0308032 v18 Aug. 2003, http://arxiv.org/html/physics/0308032).

In 2005, Droscher and Hauser proposed that the vacuum includes attractive and repulsive particles that cause gravitational effects. A particle and antiparticle are generated in a pair from the vacuum itself by the effect of vacuum polarization by virtual electrons, under the presence of a very strong magnetic field. Due to particle pair production, the total energy extracted from the vacuum is zero. (“Heim Quantum Theory for Space Propulsion Physics, for Space Propulsion Physics”, Walter Droscher and Jochem Hauser AIP Conference Proceedings—Feb. 6, 2005—Volume 746, Issue 1, pp. 1430-1440).

In the November 2005 U.S. Pat. No. 6,960,975, I disclosed a space vehicle propelled by the electro-magnetically changed properties of vacuum, particularly the pressure of inflationary vacuum state. A cooled hollow superconductive shield of the vehicle is energized by an electromagnetic field resulting in the quantized vortices of lattice ions projecting a gravitomagnetic field that forms a spacetime curvature anomaly outside the space vehicle. The spacetime curvature imbalance, the spacetime curvature being the same as gravity, provides for the space vehicle's propulsion.

A few days later in November 2005, Robert Park dismissed my invention as an inoperable. He told NATURE Journal: “If you design an anti-gravity machine, you've got a perpetual-motion machine . . . Shield half of a wheel from gravity and it will keep turning forever” (“Antigravity craft slips past patent officers” by Philip Ball, Nature 438, 139, 10 Nov. 2005). Park failed to notice that the space vehicle of my invention employs a powerful nuclear plant that develops energy greater than the gravitational pull by the height to which the vehicle is lifted.

In his examination of my November 2005 patent, Jack Sarfatti noticed that the “lattice ions” should be defined as Cooper pairs. Sarfatti also suggested that the gravitational effect is very weak (“Dr. Jack Sarfatti's comments on the U.S. Pat. No. 6,960,975 Volfson”, http://marsdrive.com/node/194).

Also in November 2005, scientists led by Clovis de Matos and Martin Tajmar and funded by the European Space Agency, published a paper on their research of gravitomagnetism. They measured the gravitational equivalent of a magnetic field in a laboratory by rotating a superconductor ring at 6,500 revolutions per minute. The scientists found that, under certain conditions, the gravitomagnetic effect is much greater than expected from general relativity. However, at just 100 millionths of the acceleration due to the Earth's gravitational field, the effect, which the scientists identified as the Gravitomagnetic London Moment, is very weak. Unlike Podkletnov who used the Type II superconductor, de Matos and Tajmar used a Type I superconductor (“Gravitomagnetic London Moment and the Graviton Mass Inside a Superconductor”, C. J. de Matos and M. Tajmar, Physica C Volume 432, Issues 3-4, 15 Nov. 2005, Pages 167-172). The relative weakness of the artificially-generated gravitational effect makes it necessary to consider amplification before this effect could be used in many practical applications.

In June 2006, Anthony Kent at al offered an idea for a new device for sound amplification by stimulated emission of radiation or SASER that emits an amplified beam of acoustical terahertz phonons (“Acoustic Phonon Emission from a Weakly Coupled Superlattice under Vertical Electron Transport: Observation of Phonon Resonance”, A. J. Kent et al, PhysRevLett.96.215504, Jun. 2, 2006).

The structure of the device, which includes a gallium arsenide/aluminum arsenide (GaAs/AlAs) semiconductor superlattice, is somewhat similar to that of a distributed-feedback optical laser. The weekly-coupling superlattice is the gain medium of the SASER structure, in which electron population inversion for phonon emission is achieved by passing an electrical current. The superlattice confines the phonons and it acts like a distributed-feedback cavity.

### DISCUSSION ON THEORY OF PRESENT INVENTION

The above-described discoveries and theories bring us closer to understanding gravitational energy and ways to affect its two main effects: repulsion and gravity. Conquering these effects would benefit humanity in many different ways.

Consider that a crystal lattice permeates the vacuum throughout the Universe. This crystal vacuum lattice is comprised of electrons and positrons (Simhony). The crystal is nearly perfect with black holes and Supernovas causing “imperfections” deforming otherwise identical unit cells of the crystal. Unlike Simhony, I believe that the electrons and positrons comprising the unit cells of this lattice are virtual (pure energy), not massive. This opinion is supported by the Michelson-Morley experiment and the subsequent tests and experiments.

Most scientists today believe in the very substantial presence of dark energy in the Universe. There is a possibility that this energy is represented by virtual particles comprising the crystal lattice of the vacuum. The presence of such a lattice explains the effects laying the foundation of this invention. To validate of the theory supporting this invention, it is not important whether the particles forming unit cells of the crystal vacuum lattice are virtal or real. Furthermore, the invention would work as intended regardless of the composition of the lattice and the unit cell structure.

Consider the natural vibrations in the crystal vacuum lattice. These vibrations are caused by the microwave background radiation heating the crystal vacuum lattice to 2.7279 degrees K. The lattice vibrations take the form of collective modes, which propagate through the vacuum lattice. These collective modes cause de Broglie elastic deformation of the unit cells and produce gravitational effects. This is why the collective modes of these naturally-occurring vibrations are sometimes called “gravity waves”. The discrete units of the gravity waves are phonons produced in pairs by the vacuum lattice, a phonon that causes gravity and an anti-phonon that causes repulsion in each pair.

Gravity waves propagate at the speed of light (“General Relativistic Model for Experimental Measurement of the Speed of Propagation of Gravity by VLBI”, S. Kopeikin and E. Fomalont, Proceedings of the 6^{th} European VLBI Network Symposium June 25-28 2002, Bonn, Germany, 4 pages). The propagation of vibration through the vacuum lattice matches the speed of light as well. There are other similarities between the graviton flow and the vibration of crystal lattice of the vacuum that will be discussed later in this chapter.

Droscher and Hauser hypothesized that the photon-like particles are capable of affecting gravity. They called these particles “gravitophotons”. However, their definition can now be made more specific. De Matos-Tajmar and Podkletnov's experiments have shown that Cooper pairs in a superconductor generate a field that, when projected from a superconductor into a vacuum, effects gravity. The positive energy, extractable from the Cooper pairs, is the vibration energy of the lattice that binds electrons into pairs. This vibration energy is quantifiable as phonons (and not photons as thought by de Matos and Tajmar). There is an important difference between the de Matos-Tajmar and Podkletnov experiments. The Type II superconductor, used by Podkletnov, appears to align Cooper pairs to project the gravitomagnetic force forward above the disk, while with the Type I superconductor, used by de Matos and Tajmar, the gravitomagnetic force formed a field around the disk.

In the de Matos-Tajmar and Podkletnov's experiments, the naturally-occurring elastic vibration, propagating throughout the crystal lattice of the vacuum and causing inertia and gravity, was affected by the newly-introduced, artificially-generated vibrations quantifyable as phonons. Each phonon binding a Cooper pair has the energy that, when converted in mass, equals the mass of a hypothetical particles graviton. This is why the phonon energy was mistaken for mass by Clovis de Matos and Martin Tajmar. One may now choose to adapt a new term “gravitophonon” (and not “gravitiphoton” as suggested by Droscher and Hauser). I have identified gravitophonons as massless bosons each having a spin of 0 (graviton is considered to have a small mass and a spin of 2). Gravitophonons are characterized by a short wavelength of 1.24×10⁻¹⁴ meters (derived from the Simhony's definition of the unit cell of the crystal lattice of the vacuum). Furthermore, gravitophonons carry a relatively small energy of 2.43×10⁻³⁴ Joules (calculated by converting the “mass” of the Cooper pair -joining photon measured by de Matos and Tajmar, into energy). Gravitophonons are generated by the vacuum's crystal lattice in pairs: a gravitophonon and an anti-gravitophonon. Gravitophonons interact with matter causing gravity. Anti-gravitophonons cause repulsion and the expansion of the Universe. The term “gravitophonon” is not yet accepted by the “mainstream” science. In order not to create a confusion and controversy, I will continue using the term “phonon” throughout this document.

The experiment set by Kent et al provides the empirical evidence of phonons' population inversion in a superconductor. Since phonons are bosons, in the process of a population inversion they interfere constructively superposing into bundles. Since Cooper pairs in the Bose regime are also bosons, they also superpose into bundles. Superimposed phonons, separated (by the electric charge) from the superimposed Cooper pairs (most likely “Cooper molecules”), are obviously of the optical type. This definition of optical phonon comes from the comparison of the effect of radiation on ionic alkali halide salts and on the alkali halide salt-like crystal lattice of the vacuum (Simhony). In both cases, optical phonons are easily excited by radiation, infrared or cosmic. The frequency of the optical phonons of the vacuum of space correspond to a mode of vibration where positrons and electrons at adjacent lattice sites swing against each other.

Consider two artificially-created bundles of superposed optical phonons. The first bundle has a vibration wave coinciding in frequency and phase with the natural vibration of the crystal lattice of the vacuum. In the second bundle, phonons (in-fact, anti-phonons) have the same frequency as the natural vibration of the lattice as in the first bundle, but their sinusoidal wave is inverted (180 degrees out of phase). Now let us inject these two artificially-created bundles, one-by-one, into two different elastic unit cells of the crystal lattice of the vacuum.

When the first bundle enters a first unit cell, because of the natural vibration of the lattice, the first unit cell is already in a Broglie elastic deformation cycle. Consider that the first bundle enters the first unit cell at the moment when the virtual electrons of the cell are moving closer together and the virtual positrons are moving farther apart. Then the first bundle, having a strong positive charge, pulls the (negatively-charged) virtual electrons even closer together and repels the (positively-charged) virtual positrons even farther apart. Upon the first bundle's departure, the first unit cell recovers and then overcompensates to a much greater degree than it would without the first bundle passing through it.

In physical terms, there are two waves, one naturally-occurring and one artificially-created, in the process of a constructive interference. In mathematical terms, we describe two bundles of superposed optical phonons in the process of further superposition. The ripple of the amplified vibration propagates through the lattice unit cells. Such amplification of natural vibration of the crystal lattice by the first bundle causes a temporary and local increase in the gravitational energy of the vacuum. An increase in the gravitational energy of the virtal particles of the vacuum is associated with the gravitational time dilation and space contraction.

The second bundle is identical to the first bundle except for its inverted phase. This means that the second bundle enters a second unit cell at the moment when the virtual electrons of the second unit cell are moving farther apart and the virtual positrons are moving closer together. Then the second bundle, having a strong positive charge, acts to pull the (negatively-charged) vitual electrons closer together and repel the (positively-charged) virtual positrons farther apart. In physical terms, the result of the destructive interference of two waves, one naturally-occurring and another artificially-created, is a dampened, completely stopped, or even reversed vibration of the lattice. In mathematical terms, we can describe one bundle partially neutralizing another, or two bundles canceling out each other.

The result on the crystal lattice of the vacuum would be a dampened ripple of wave, absence of any ripple, or an inverted (180 degrees out of phase) ripple. The reduction in the ripple of natural vibration of the lattice, caused by the entry of the second bundle, results in a temporary and local reduction in the gravitational energy of the vacuum. A reduction in the gravitational energy of the virtual particles of the vacuum is associated with the gravitational time contraction and space dilation. A complete ripple stop results in a complete, temporary, and local elimination of the gravity effect.

In the case of the second bundle, if the artificially-created wave is stronger than the naturally-occurring one, the direction of the propagation of the gravitational energy would change 180 degrees. Eventually, the interaction of the virtual particles of the vacuum with the artificially created bundle of superposed phonons would lead to a resumption of the natural lattice vibration: the bundle's lifetime is finite. However, the device of this invention sustains the anomaly by emitting new artificially created bundles of superposed phonons for as long as the energy is available.

Consider the existing and claimed machines for phonon emission Podkletnov has reported that in the early 1990's in Tempere, Finland, he used 6 solenoid coils at 850 Gauss each at a high frequency current of 10⁵ Hz. The thickness of the toroidal disk used by Podkletnov was 10 mm. The system's reported efficiency reached 100% and the total field in Podkletnov's disk was reported to be about 0.5 Tesla. The system emitted individual phonons (not bundles). The maximum weight loss reported by Podkletnov was 2.1%

In 2003, Ning Wu showed the dependency between the thickness of gravitational shielding Δrₒ, and the relative gravity loss ε:

ε≈Δrₒ*m_{g}

where m_{g} is the mass of a graviton in the locale. According to Ning Wu's calculations, the 10 mm disk, such as one used in Podkletnov's 1992 Tampere experiment, could cause a relative gravity loss of 0.03% (“Gravitational Shielding effects in Gauge Theory of Gravity”, Ning Wu, arXiv:hep-th/0307225 v 1, 23 Jul. 2003). However Ning Wu didn't take into account the efficiency losses estimated by Skeggs to be at 56%. Skeggs suggests that in the Podkletnov's machine, out of the 850 Gauss developed on the coil surface, the field affecting the superconductor is only 400 Gauss (“Engineering Analysis of the Podkletnov Gravity Shielding Experiment, Peter L. Skeggs, Quantum Forum, Nov. 7, 1997, http://www.inetarena.com/˜noetic/pls/podlev.html, 7 pages).

Neither Ning Wu nor Skeggs considered strong scattering losses caused by the boundaries between crystallites of the polycrystalline media of the Type II superconductor used by Podkletnov. Though these losses are difficult to calculate, it is reasonable to assume that they were in the 50% range. Thus, the actual gravity loss in the Tempere experiment could be estimated to be below 0.01% of the Earth's gravity, a number in line the experimental data from de Matos-Tajmar experiments. Even if Podkletnov's reading was inaccurate, it doesn't diminish his accomplishment in constructing a successful gravitational device.

In order to achieve the maximum weight reduction claimed by Podkletnov, the thickness of the superconductor would have to be nearly 10 meters. To reach complete weightlessness on the surface of the Earth with the Podkletnov's machine, the superconductor would have to be 500 meters thick, which is, obviously impractical. It is worth noting that Podkletnov has explained the performance of his device by the relatively large disk diameter of 30 centimeters. Podkletnov stated that in order for the device to be effective, the disk's radius must exceed the Schwarzschild radius. Both Tamjar and Wu disagreed stating that the gravitomagnetic field depends only on the disk's angular velocity, charge-to-mass ratio (Tamjar) and thickness (Wu).

In order to resolve the problem of the weakness of the gravitational anomaly provided by his earlier machine, Podkletnov developed an Impulse Gravity Generator (“Impulse Gravity Generator Based on Charged YBa_{—}2Cu_{—}3O{7-y} 5Superconductor with Composite Crystal Structure”, E. Podkletnov & G. Modanese, http://xxx.lanl.gov/abs/physics/0108005 3 Aug. 2001 32 pages, 7 figures.) This solution reportedly provided a high-intensity coherent beam of gravitational force affecting gravity by up to 9%.

In their 2002 paper, Chris Y. Tailor and Giovanni Modanese proposed employing the new impulse gravity generator to direct, from an outside location, an “antigravity” beam toward a spacecraft, this beam acting as a repulsive force field producing propulsion for the spacecraft. (“Evaluation of an Impulse Gravity Generator Based Beamed Propulsion Concept”, Chris Y. Taylor and Giovanni Modanese, American Institute of Aeronautics and Astronautics, Inc., 2002). However, the impulse gravity generator was not suitable for this particular application because its powerful, nanosecond-long gravitational bursts would harm pilots and cause severe structural and electrical damage to the spacecraft. The use of Podkletnov's impulse gravity generator in other applications is limited by the device's large size and high-energy requirements (reportedly, it is powered by a 5 million Volt energy source). These drawbacks underline the need for a powerful, energy-efficient, and portable projector of on-demand impulse or continuous beam of gravity-modifying phonons.

### OBJECTS OF THE INVENTION

The first and the most general object of this invention is to resolve problems typical for the first generation of the gravitational energy devices, these problems being the relative weakness of the produced force and its impulse nature. A device of this invention is to be an efficient source of gravitational energy that generates a coherent, collimated, and high-energy beam. It would be specifically advantageous for some applications to be able to switch the device from emitting a continuous beam emission to the impulse beam, and vice versa.

Consider the only known source of artificially-created gravitational energy, a rotating superconductor. In a flat, cooled superconductor disk, the electrons are bound into Cooper pairs energized at a ground level. Released into a vacuum, the phonons (initially formed to pair the electrons into Cooper pairs) affect the crystal lattice of the vacuum causing gravitational effects. It is clear that to achieve the goal of a dramatic increase of the gravitational energy output while not raising the Cooper pairs' energy to higher levels, one needs to increase the thickness of the superconductive disk and apply great amounts of energy. A very long rod of superconductive material, stimulated by a large number of powerful electromagnets disposed along this rod, could provide many layers of Cooper pairs. The phonon energy, released by this multilayered generator, adds up into a relatively high-energy beam. However, the cost of a very long high-temperature superconductor rod would be very high. The energy requirements would be very high as well. In order to make the device more portable, practical and efficient, but still very powerful, signal amplification is required.

Kent at al has shown that the population could be inverted in both the photon amplifiers and the phonon generators. One could then conclude that the solution for the problem of the weakness of the gravitational energy beam is available in the 50 year old art of light and microwave amplification by stimulated emission of radiation.

Thus, the second, and more specific, object of this invention is the adaptation of the amplification concepts used in lasers and masers to vibration energy amplification by stimulated emission of radiation. In order to emit a more powerful beam, it is required to amplify the gravity-affecting waves before they are emitted (these amplified waves mathematically expressed as bundles of superposed phonons). It is important to note that all the previously known gravity-affecting devices emitted single phonons, not their bundles. The bundles of superposed phonons, upon the transition from a crystal lattice of the device of this invention into the crystal lattice of the vacuum, amplify, dampen, completely stop, or invert the natural lattice vibrations, thus locally affecting the gravitational energy.

Thus, the third and the most specific object of this invention is the development of a phonon maser emitting a collimated, coherent, and powerful beam of the bundles of superposed phonons, this beam, continuously or in impulses, affecting the local gravity or repulsion forces.

Aerospace represents some of very important applications for this invention. An air- or spacecraft could be launched and landed by, or with the assistance of, the phonon maser. The cost of sending a payload into orbit would be dramatically reduced. Or the phonon maser could aim its beam at a space target to correct a satellite's orbit or deflect an approaching comet away from the Earth. A built-in telescope or laser would assist in aiming the phonon maser at the space target.

Wireless communications provide other uses for the phonon maser. Unlike radio, light, or microwave signals, the phonon maser beam cannot be obstructed or distorted by physical objects (atmosphere, water, structures, precipitation, mountains, etc.). Because the phonon maser could transmit a signal to a receiving station through the mass of the Earth, one transmitter may replace a system of communication satellites that costs many billions of dollars to build and deploy.

There are yet more applications of this invention in the wireless power transmission. Construction of a power grid is an expensive enterprise. The phonon maser could transmit power onto a distant flywheel driving an electrical generator with no investment into infrastructure.

Another application of this invention is in medicine. With the phonon maser or masers, the defective tissues or foreign bodies could be moved within, or removed from, a patient without making incisions. The none-invasive surgeries with the phonon maser could be relatively inexpensive, quick, safe, and result in greatly reduced hospital stays.

Still another application of this invention is as a spaceship engine. Such an engine could be comprised of two phonon masers. One phonon maser could project a powerful beam of the bundles of superposed phonons in one direction, and another phonon maser could project a similarly powerful beam of the bundles of superposed anti-phonons in the opposite direction. By creating repulsion (and expanding spacetime) behind the spaceship and creating gravity (and contracting spacetime) in front of it, the spaceship engine could generate high-speed propulsion.

Many other applications for the phonon maser will become obvious in the future. The embodiments, most appropriate for these new applications and broadly based on this invention, are within the scope of this invention.

### SUMMARY OF THE INVENTION

A new method and device for vibration energy amplification by stimulated emission of radiation, are disclosed. The field of amplification devices emitting energy in a coherent beam, until now mainly represented by lasers (photon emitters) and masers (microwave emitters), is now being expanded to include a device that emits quantized amplified vibrations.

The device of this invention is a phonon maser. The phonon maser is comprised of a resonant cavity, a superconductive gain medium, and pumping means. The resonant cavity is comprised of highly reflective means and partially reflective means. The superconductive gain medium and the pumping means rotate against each other at high speed. The superconductive gain medium is a cooled superconductor. On the preferred embodiment, the superconductive gain medium is a high-temperature, crystalline superconductor. In one of the other embodiments, the superconductive gain medium is a single crystal.

The pumping means generate energy in the form of an electromagnetic field. This energy is absorbed by the superconductive gain medium to produce physical vibrations. The vibrations are quantized as phonons. The phonons bind electrons into Cooper pairs. Cooper pairs and free phonons bounce in the superconductive gain medium between the highly reflective means and the partially reflective means. This bouncing in the background of a continued supply of new phonons and new electrons causes constructive interferences resulting in the excited states in Cooper pairs. In Bose regime, it is likely that the “excited Cooper pairs” are actually “Cooper molecules” with more than two electrons in a molecule. In order not to create confusion and controversy, unless noted otherwise, I will continue using a more general and accepted term “excited Cooper pairs”.

When the number of Cooper pairs in one excited state exceeds the number of Cooper pairs in a lower energy state, a population inversion is achieved. In this condition, free phonons, bouncing in the superconductive gain medium, produce more stimulated emission than stimulated absorption.

In a Bose regime, free phonons bundle together into bundles of superposed free phonons, while the binding phonons in the excited Cooper pairs bundle together into bundles of superposed binding phonons. Amplified by the population inversion, the identically-charged bundles interfere with each other constructively, raising the Cooper pair energy to ever higher levels. Eventually, the bundles of free phonons break through the partially reflective means and enter the vacuum as a coherent beam of bundles of superposed guest phonons. The coherent beam of bundles of superposed guest phonons may be continuous or, through application to the Cooper pairs of energy greater than the gap, impulsed. The coherent beam of bundles of superposed guest phonons affects the vibration of the crystal lattice of the vacuum, locally affecting gravity and repulsion forces.

### BRIEF DESCRIPTION OF THE DRAWINGS

FIG. 1 is a perspective view of the preferred embodiment of the device of this invention.

FIG. 2 is part side view, and part schematic diagram, of the preferred embodiment of the device of this invention.

FIG. 3A is a modified Feynman diagram showing a weak coupling of a Cooper pair.

FIG. 3B is a modified Feynman diagram showing a strong coupling of a Cooper pair.

FIG. 3C is a modified Feynman diagram showing a Cooper pair after it absorbs a second free phonon.

FIG. 3D is a modified Feynman diagram showing a Cooper pair after it absorbs a bundle of two superposed free phonons.

FIG. 4A is a diagram showing a cross-section of a superconductive gain medium with a multitude of weakly coupled Cooper pairs at a ground bound state in the weak coupling condition of the BCS regime.

FIG. 4B is a diagram showing a cross-section of the superconductive gain medium with a multitude of strongly coupled Cooper pairs at a ground bound state in the strong coupling condition of the Bose regime.

FIG. 4C is a diagram showing a cross-section of the superconductive gain medium with a multitude of Cooper pairs at the second exited state.

FIG. 5A is a schematic diagram showing the side of an undistorted cubic unit cell of the vacuum crystal lattice.

FIG. 5B is a schematic diagram showing the side of a distorted cubic unit cell.

FIG. 5C is a three-dimensional schematic diagram of the distorted cubic unit cell.

FIG. 5D is a three-dimensional schematic diagram of the distorted cubic unit cell centrally positioned in a single cell thick slice of the crystal lattice of the vacuum.

FIG. 6A is a diagram illustrating an example of practical application for a method of creating and emitting coherent beams of bundles of guest phonons.

FIG. 6B is a diagram illustrating another example of practical application for the method of creating and emitting the coherent beams of bundles of guest phonons.

### DRAWINGS—REFERENCE NUMERALS

1 phonon maser

2 resonant cavity

3 superconductive gain medium

4 pumping means

5 support structure

6 highly reflective means

7 partially reflective means

8 void

9 highly polished surface

10 partially polished surface

11 highly reflective material layer

12 partially reflective material layer

13 highly reflective superconductor

14 partially reflective superconductor

15 energy source

16 highly reflective end electrode

17 partially reflective end electrode

18 back-beam shield

19 superconductive gain medium electric motor

20 weakly coupled Cooper pair at a ground bound state

21 weakly binding phonon

22 first free phonon

23 strongly coupled Cooper pair at a ground bound state

24 second free phonon

25 strongly binding phonon

26 Cooper pair at the first excited state

27 bundle of two superposed binding phonons

28 bundle of two superposed free phonons

29 Cooper pair at the second excited state

30 bundle of four superposed binding phonons

31 low-temperature superconductor

32 vibration force vector of weakly coupled Cooper pair at a ground bound state

33 vibration force vector of strongly coupled Cooper pair at a ground bound state

34 vibration force vector of Cooper pair at the second excited state

35 coherent beam of bundles of superposed guest phonons

36 undistorted cubic unit cell

37 distorted cubic unit cell

38 bundle of superposed guest phonons

39 target

40 initial location

41 desired location

42 spaceship

43 spaceship engine

44 first phonon maser

45 second phonon maser

46 coherent beam of bundles of superposed guest anti-phonons

### DESCRIPTION OF THE PRESENTLY PREFERRED EMBODIMENT

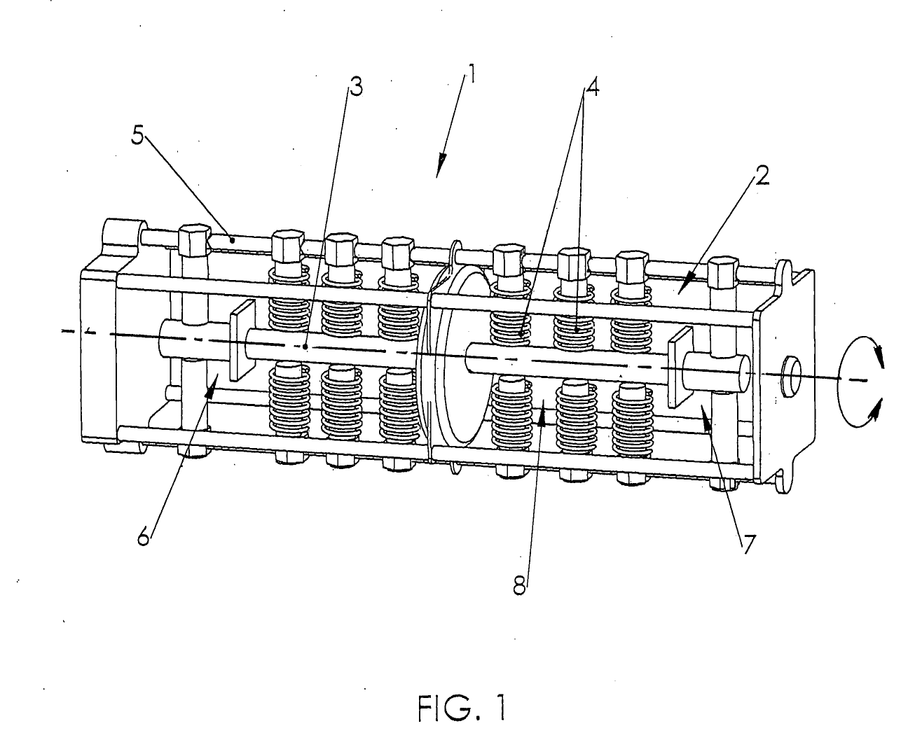

FIG. 1 shows a perspective view of the preferred embodiment of the device of this invention.

A phonon maser 1 is comprised of a resonant cavity 2 and a superconductive gain medium 3, the medium 3 disposed in the cavity 2. In the superconductive gain medium 3, quantum mechanical effects, often called stimulated emission, amplify the vibration of unit cells of the crystal lattice of the superconductive material of the medium 3.

In order for the device of this invention to operate, the superconductive gain medium 3 must be pumped by an external energy source, and this pumped energy converted into the energy of lattice vibrations. Pumping means 4 provide the required energy in the form of electromagnetic energy. Unlike an active medium in a conventional maser, the superconductive gain medium 3 in the phonon maser 1 must be pumped dynamically (in rotation). This is why the superconductive gain medium 3 and the pumping means 4 are disposed rotatably to each other.

A support structure 5 supports the superconductive gain medium 3 and the pumping means 4 in a position that provides for their relative rotation. The support structure may be comprised of several elements welded to each other or interconnected by simple fasteners (not shown).

In order to supply the energy needed to create a Fermi sea of electrons in the superconductive gain medium, this sea providing material for the formation of future Cooper pairs, on a preferred embodiment the pumping means 4 are executed as solenoid coils or electromagnets. On the preferred embodiment, energy is pumped into the superconductive gain medium 3 in the form of a high-frequency electromagnetic flux. A skilled in the art may envision the pumping provided by many other forms of energy from various types of energy sources, all within the scope of this invention.

In order to convert the incoming energy into the sought-after lattice vibrations, on the preferred embodiment the superconductive gain medium 3 is executed as a substantially elongated superconductive cylinder cooled to a temperature providing superconductivity in the medium 3. On another embodiment, the superconductive gain medium 3 is a toroidal cylinder with a pivotable cylindrical element (not shown) of the support structure 5 centrally protruding through the medium 3.

A free electron, as it spins while moving through a superconductor, causes a vibration of the crystal lattice that could also be described as an increase in the concentration of positive charges in the lattice around the free electron. This increase in turn attracts another free electron with an opposite spin. Two electrons are then held together with a certain binding energy. A quantum of this energy—a phonon—represents a quantized mode of vibration in the crystal lattice of a superconductor. Phonons bind free electrons into Cooper pairs that float in the Fermi sea of electrons.

In the preferred embodiment, the superconductor material for the superconductive gain medium 3 is selected to produce vibrations, which, upon emission into a vacuum, coincide with the natural vibration of the unit cells comprising the crystal lattice of the vacuum.

It has been observed in lasers that the boundaries between crystallites of the polycrystalline media cause strong scattering losses. Single crystal lasers became the gold standard for high-coherency, energy-efficient radiation. In order to reduce scattering losses, it would be advantageous to execute the superconductive gain medium 3 as a single crystal high-temperature superconductor. In 1997, Y. Shiohara and X. Yao reported growing NDBCO and Y(Sm)BCO single crystals of about 25 mm. Both superconductors perform in the 90K degree range, a temperature that would be easily achievable by using an inexpensive and commercially available nitrogen as a coolant. (“Large REBCO Single Crystals: Growth Processes and Superconductive Qualities”, Superconductive Science Technology, 10, No. 5 May 1997, pp. 249-258). Newer technologies allow welding of the aligned REBCO or YBCO crystals. In the preferred embodiment of the phonon maser 1, the superconductive gain medium 3 is made from welded together large crystals that are pre-aligned to behave as a single crystal.

The length of the superconductive gain medium 3 on the preferred embodiment is 60 centimeters (cm), and the diameter—5 cm. In this embodiment, twenty (20) 2 cm—thick, 5 cm in diameter crystals are fused together.

But some applications require much larger superconductive gain medium sizes. This represents a problem: there is a development gap between the available single crystal superconductors and those required for the phonon maser capable of launching satellites.

Also, the length of time required to grow a large superconductor crystal affects the crystal's cost. This is why, in another embodiment of the phonon maser 1, the superconductive gain medium 3 is made from a high-temperature ceramic superconductor with the well-organized crystallite structure. An example of such a superconductor is YBa₂Cu₃3O_{7-y}, used by Podkletnov in his research.

The superconductive gain medium 3, executed as a single crystal, represents still another embodiment suitable for applications in which a portable configuration of the phonon maser could be used. An example of such an application is wireless communication.

Various materials may be used for different applications, these materials including the YBCO-based ceramics, or even possibly non-ceramics such as Nb—Ti and MgB2. A skilled in the art may still choose another type of material for the superconductive gain medium 3 that allows the formation of Cooper pairs in a Bose regime, all within the scope of this invention.

The pumped energy must be retained in the superconductive gain medium 3 until saturation allows the amplification to take hold. In order to reflect particles on their way out of the superconductive gain medium 3 back into the medium 3, the resonant cavity 2 is comprised of highly reflective means 6 on one end of the medium 3, and partially reflective means 7 on an opposite end of the medium 3. The highly reflective means 6 are specified as “highly” because of their level of particle reflection, which is higher than that of the partially reflective means 7. The actual reflection rate varies depending mainly on the particle size and energy. There is a void 8 disposed between the highly reflective means 6 and the partially reflective means 7. The void 8 fully envelopes the superconductive gain medium 3.

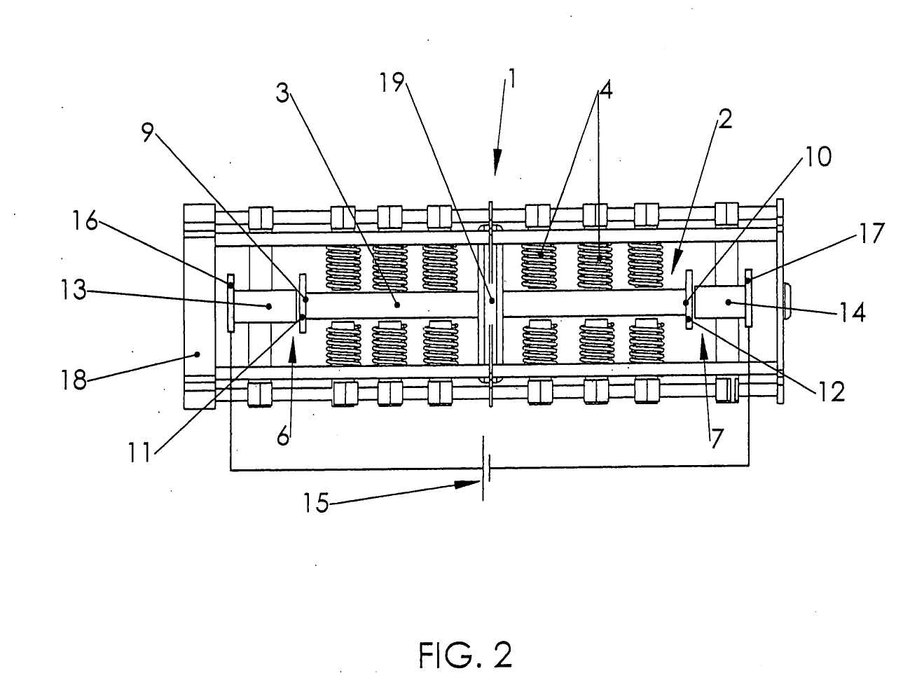

FIG. 2 shows a part side view and part schematic diagram, of the preferred embodiment of the device of this invention.

In 1986, Jane Throwe successfully reflected high-frequency phonons off a highly polished wall of a silicone crystal. The reflecting surface was polished ether with 1 (mu) diamond paste, or with a chemi-mechanical silica sol (Syton). (“Phonon Reflection in Silicon”, 1986 Ph.D. in physics dissertation of Jane B. Throwe, Library of Indiana University, Blumington IN 1986, Abstract: Dissertation Abstracts International, Volume: 47-05, Section: B, page: 2051, 1986).

Cooper pairs in the Bose-Einstein condensate (BEC), having radii of gyration smaller than the inter-pair spacings, are bosons. Phonons are bosons as well. The experiments done by Throwe and other researchers provide strong evidence that most bosons are reflected by highly-polished crystal surfaces. The shorter is the boson's wavelength, the greater surface polish of the reflector is required. The polished surfaces are also effective in arresting fermions such as electrons. This is why the highly reflective means 6 comprise a highly polished surface 9 of the superconductive gain medium 3 on the end of the medium 3.

The partially reflective means 7 comprise a partially polished surface 10 of the superconductive gain medium 3 on the opposite end of the medium 3. The highly polished surface 9 is specified as “highly” because of its level of surface quality, which is higher than that of the partially polished surface 10. Because the higher reflective quality of the highly polished surface 9 over the partially polished surface 10, phonons and other particles break through the partially reflective means 7 before they could break through the highly reflective means 6.

Many researchers have applied film to the polished surfaces in order to better reflect the particles reaching the polished surfaces of the superconductive gain medium 3 back into the medium 3. For example, Throwe utilized an oxide layer that forms on silicon on contact with air, altering it in basic and acidic peroxide solutions. The oxide layer was also subjected to etching. As material for the reflective film, some researchers used a superconductor with a crystalline lattice, which is most reflective when complimented by cooling to a low temperature. Other researchers used insulator films, which are most effective when complimented by applying voltage.

This is why the highly reflective means 6 may include a highly reflective material layer 11 disposed on the highly polished surface 9 of the superconductive gain medium 3. On the preferred embodiment, the highly reflective material layer 11 may be YBCO film 500 nm thick. The partially reflective means 7 may include a partially reflective material layer 12 disposed on the partially polished surface 10 of the superconductive gain medium 3. On the preferred embodiment, the partially reflective material layer 12 may be an YBCO film 200 nm thick. The highly reflective material layer 11 is specified as “highly” because of its level of particle reflection, which is higher than that of the partially reflective material layer 12.

Furthermore, the highly reflective means 6 may include a highly reflective superconductor 13 disposed next to the highly reflective material layer 11 longitudinally to the superconductive gain medium 3. The partially reflective means 7 may include a partially reflective superconductor 14 disposed next to the partially reflective material layer 12, also longitudinally to the superconductive gain medium 3. The highly reflective superconductor 13 is specified as “highly” because, under proper cooling, its level of particle reflection is higher than that of the partially reflective superconductor 14. The highly reflective superconductor 13 and the partially reflective superconductor 14 could be executed as substantially elongated cylinders made of high-temperature, crystalline Type II superconductors identical or similar in their chemical composition to that used in the superconductive gain medium 3.

On the preferred embodiment, the highly reflective superconductor 13 and the partially reflective superconductor 14 do not rotate. On another embodiment, the highly reflective superconductor 13 and the partially reflective superconductor 14 rotate with the superconductive gain medium 3. On this embodiment, the highly reflective superconductor 13 and the partially reflective superconductor 14 may be pumped by the pumping means 4 with the electromagnetic energy.

In the preferred embodiment, the highly reflective superconductor 13 and the partially reflective superconductor 14 assist the particle reflection by providing for the Josephson effect in the highly reflective material layer 11 and the partially reflective material layer 12 (in combination with the applied voltage). In another embodiment, the highly reflective superconductor 13 and the partially reflective superconductor 14 assist in particle reflection by creating particle bottlenecks (in combination with deep cooling). The Josephson effect is well-researched and requires no additional comments. It has been shown that the reflective qualities of the resonant cavity substantially improve if the reflective means are cooled to a temperature in the single digits on the Kelvin scale. The reasons for this improvement are still being debated by the scientists. Let us now review possible reasons for this improvement, starting with fermions, specifically electrons and clusters of electrons.

One reason for improved reflective qualities at low temperatures could be a substantial slowdown of particle movement under conditions of near-zero temperature, and the ability of fermions to pack densely in cold matter. Such low-temperature conditions lead to a bottle-neck effect where electrons form an obstruction. Because of the Pauli exclusion principle, only a finite number of electrons could be absorbed and, because of the Coulomb force, the newly approaching electrons are repelled back into the superconductive gain medium, thus maintaining a dense Fermi sea within the medium.

In the case of bosons (Cooper pairs in BEC and phonons) that don't obey the Pauli exclusion principle, the nature of the “bottlenecks” is yet to be well explained, but numerous experiments indicate the presence of such bottlenecks. Among the existing hypotheses, there is one suggesting that photons and phonons couple on the edges of crystals and in films of superconductive materials, where they form polaritons. The polaritons scatter and, because of their low group velocity at low temperature, create a bottle neck. (“Polariton Effects in Transient Grating Experiments Performed on Antracene Single Crystals”, Todd S. Rose, Vincent J. Newell, Jeffrey S. Meth and M. D. Fayer, Chemical Physics Letters volume 145, number 5, 15 Apr. 1988, pp 475-480).

Let us now review the cooling temperatures, starting with temperatures required to cool the superconductive gain medium 3. Since the preferred material for the superconductive gain medium 3 is a Type II superconductor, which is, usually, a high-temperature superconductor, the temperature may be 40—90 degrees K. The upper range of this temperature may be accomplished using readily available and relatively inexpensive liquid nitrogen.

In order to create a particle bottleneck, on the preferred embodiment the partially reflective means 7 are cooled to another temperature lower than the temperature of the superconductive gain medium 3. The another temperature may be provided by using coolants such as liquid helium or liquid hydrogen.

In order to assure that the partially reflective means 7 open up to the flow of phonons but not the highly reflective means 6, the highly reflective means may be cooled to a still another temperature lower than the another temperature of the partially reflective means. The still another temperature may be in the single degrees Kelvin and could be provided by pouring liquid helium or liquid hydrogen on the highly reflective means 6.

Another method of creating bottlenecks is the use of materials for the highly reflective means 6 and the partially reflective means 7 in which the speed of particle propagation is slower than the speed of particle propagation in the material of the superconductive gain medium 3. The materials for the highly reflective means 6 and the partially reflective means 7 are more effective in creating bottlenecks when used in-combination with the lower temperatures.

In order to assure that the partially reflective means 7 open up to the flow of particles, but the highly reflective means 6 do not, the means 6 may be executed from the material in which the speed of particle propagation is slower than the speed of particle propagation in the material of the means 7.

The method of the current invention requires resonating free phonons in the resonant cavity 2 between the highly reflective means 6 and the partially reflective means 7. Initially, free phonons are resonated individually and, after population inversion, in bundles. In order to better control processes occurring in the superconductive gain medium 3, the resonant cavity 2 may include an energy source 15. In the preferred embodiment, the energy provided by the energy source 15, is in the range of 50 keV.

A highly reflective end electrode 16 is disposed on the highly reflective means 6. The highly reflective end electrode 16 is electrically connected to the energy source 15. A partially reflective end electrode 17 is disposed on the partially reflective means 7. The partially reflective end electrode 17 is also electrically connected to the energy source 15. A controlled application of voltage from the energy source 15 to the highly reflective end electrode 16 and the partially reflective end electrode 17 assists in forming and exciting Cooper pairs and resonating particles within the resonant cavity. The application of voltage furthermore provides for switching the phonon maser from a continuous to an impulsed mode of operation. This switching is provided by breaking the population inversion by passing energy greater than the gap to Cooper pairs, and by opening and closing Josephson junctions in the highly reflective material layer 11 and in the partially reflective material layer 12.

There is still another reason for the need of the directional flow of energy between the highly reflective end electrode 16 and the partially reflective end electrode 17, this energy generated by the energy source 15. This directional flow of energy aligns Cooper pairs along the superconductive gain medium 3, the highly reflective superconductor 13, and the partially reflective superconductor 14. The alignment of Cooper pairs is required in order to bounce phonons back and forth along the superconductive gain medium 3, the highly reflective superconductor 13, and the partially reflective superconductor 14; and also to project the gravitomagnetic field longitudinally to the medium 3. Without the alignment of Cooper pairs, the gravitomagnetic force forms a field around the superconductive gain medium 3. Such a field was formed on the Tajmar machine.

In the April 2006 interview, Podkletnov mentioned that his Impulse Generator caused a back-beam harmful to living tissues (The Impulse Generator. Dr Evgeny Podkletnov on the Impulse Gravity-Generator, by Tim Ventura & Evgeny Podkletnov, Apr. 10^{th,} 2006, http://www.americanantigravity.com/documents/Podkletnov-Interview.pdf). There is a similar remark in the anonymous “Podkletnov” Wikipedia article (www.wikipedia.org/podkletnov). The back-beam in the latest Podkletnov machine was probably formed of free electrons, the byproduct of the breakdown of Cooper pairs.

The intensity of the back-beam of the phonon maser would be higher than that of the Podkletnov machine. In the phonon maser, as the result of a population inversion, the energy of electrons in the Cooper pairs rises quadratically to the ever-higher levels. The back-beam of the phonon maser could be comprised of high-energy free electrons that never formed into Cooper pairs, or became unbound by the electromagnetic energy. It is well known that high-energy electrons are harmful to living tissues.

There is another explanation for the nature of the back-beam in the phonon maser. It is, in my view, likely that, in the Bose regime, the increase in the boson energy would be represented by a quadratic increase in the number of electrons in the boson (proportional to the increase in the number of phonons). In other words, the Cooper pair is no longer a pair but a molecule formed by a cluster of electrons. The cluster of electrons could be envisioned as a toroidal cloud encircling the bundle of superposed free phonons, or a spherical cloud fully enveloping this bundle. If the bundle of superposed free phonons, which holds the cluster of electrons together, separates from the cluster, then this cluster would become an unstable fermion, sometimes defined as an Electrum Validum Object (EVO), (Observations on the Role of Charge Clusters in Nuclear Cluster Reactions by K. Shoulders & S. Shoulders, Journal of New Energy, Jul. 28 1996, 11 pages). These EVOs may form the back-beam of the phonon maser. Per Shoulders & Shoulders, each cluster of electrons could include as many as 6.0221415×10²³ electrons (the Avogadro number). The EVOs would soon explode, with each explosion releasing nearly 1.5×10⁻¹⁰ Joules of energy harmful to living tissues. The existence of the powerful back-beam could substantially limit the application of the phonon maser. It is fortunate for the humanity that the harmful back-beam is highly dispersed and only a few centimeters in-length. Therefore, the EVO emitters could not be weaponized.

It should be possible to nearly stop the back-beam emission by cooling the highly reflective means to temperatures in the single degrees K. The low-temperature conditions would lead to a bottle-neck effect where the flow of high-energy electrons (or EVOs) would slow down nearly to a stop, forming an obstruction. Because of the Pauli exclusion principle, only a finite number of electrons (or EVOs) could be absorbed and, because of the Coulomb force, the newly approaching electrons (or EVOs) would be repelled back into the superconductive gain medium.

It is also possible to provide a situation in which the electrons (or EVOs) in the Fermi sea could be held in the crystal lattice by a restraining energy exceeding the energy driving free electrons into the vacuum, the restraining energy provided by the ionization potential. The restraining energy would be generated by the condensation effect caused by electron-electron interactions. Until it is proven that the restraining energy could be reliably maintained in the system, a physical protection from the back-beam is required. This is why a back-beam shield 18 is disposed orthogonally to the superconductive gain medium 3, just outside the highly reflective means 6. On the preferred embodiment, the back-beam shield is a 2.5 cm-thick lead panel.

The phonon maser could be equipped with a telescopic and/or lasing means in order to assist aiming the maser at a target. For example, a photon pump (not shown) may be disposed at a photon-transmittable distance to the superconductive gain medium. If the superconductive gain medium is a clear single crystal, it could, along with phonons, amplify photons, hence providing the phonon maser with the additional capability of lasing the target.

On the preferred embodiment of the phonon maser 1, the superconductive gain medium 3 is rotatably disposed at an electromagnetic flux-transmittable distance from the pumping means 4. On another embodiment (not shown), the pumping means are rotatably disposed at the electromagnetic flux-transmittable distance to the superconductive gain medium.

Consider the flux requirements for providing a continuous population inversion. The preferred embodiment of the phonon maser uses 10⁵ Hz current supplied to 12 solenoid coils at 1000 Gauss each.

In theory, the above energy should provide for a high-speed relative rotation of the pumping means 4 against the superconductive gain medium 3. In practice, in order to assure the high-speed relative rotation, it may be necessary to supplement the pumping means with a motor. On the preferred embodiment, the phonon maser 1 includes at least one superconductive gain medium electric motor 19 disposed connectively to the superconductive gain medium 3. The superconductive gain medium electric motor 19 assists the rotation of the superconductive gain medium 3 against the pumping means 4 which are static. On the preferred embodiment, the superconductive gain medium electric motor 19 is a pancake motor.

On another embodiment (not shown), the phonon maser includes at least one pumping means electric motor disposed connectively to the pumping means. The pumping means electric motor assists the rotation of the pumping means against the superconductive gain medium, which is static in this another embodiment. A skilled in the art may envision still another embodiment where both, the pumping means and the superconductive gain medium, rotate.

For successful Cooper pair formation, it is important to assure that the angular velocity of rotation and the charge-to-mass ratio are both very high (Tajmar/de Matos). On the preferred embodiment, the superconductive gain medium motor 19 rotates at a speed in the 50,000-100,000 revolutions per minute (RPM) range.

A skilled in the art may elect to transfer the motion from an outside-mounted motor to the superconductive gain medium or the pumping means via a gear train, belt, or other mechanical, electromechanical, or electromagnetic means of rotational motion transfer (not shown), all within the scope of this invention. The means of rotational motion transfer may raise the rotation speed to 1 million RPM, or higher. In order to accommodate this very high rotation speed, on one of the embodiments, the superconductive gain medium or the pumping means are supported by hydrostatic bearings combined with a “frictionless” superfluid (not shown).

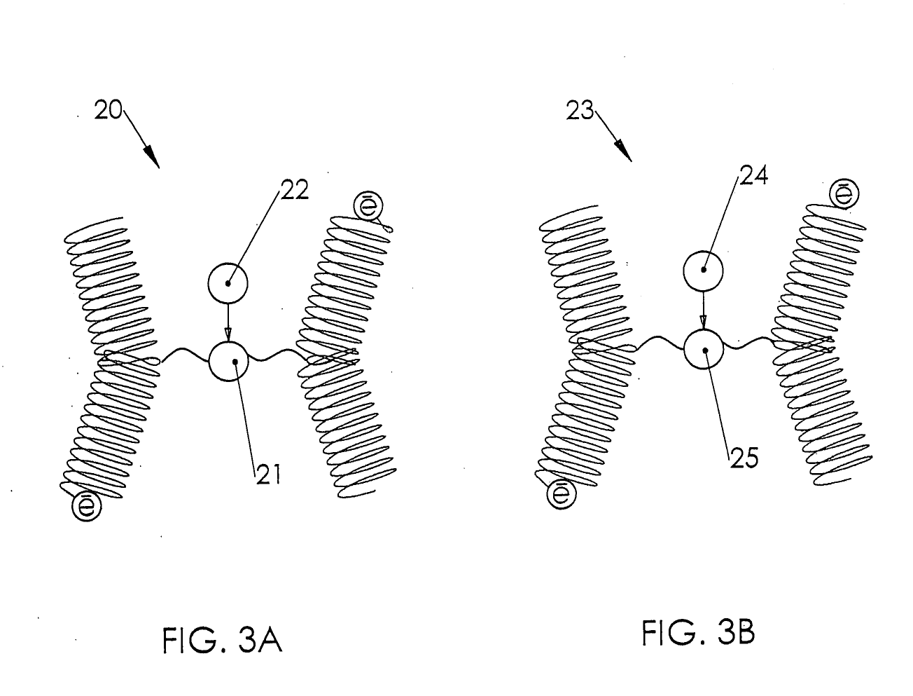

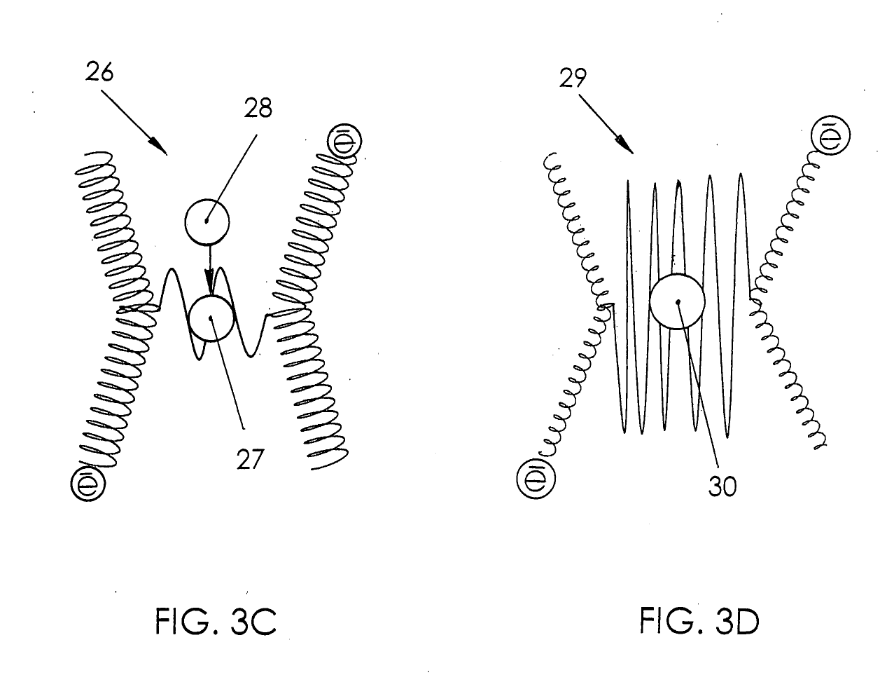

FIG. 3A is a modified Feynman diagram showing a weak coupling of a Cooper pair. Consider a situation where a multitude of weakly coupled Cooper pairs at a ground bound state 20 flows in a conventional (low temperature) Type I superconductor. Weak coupling of Cooper pairs at this low energy level is well investigated. The distances between the weakly coupled Cooper pairs are smaller than the distances between electrons within these pairs. This condition provides for a weak coupling of Cooper pairs, also called the Bardeen, Cooper, and Schrieffer (BCS) regime. The electrons within the weakly coupled Cooper pair at a ground bound state 20 are positioned at a considerable distance from each other, held together by a relatively weak low-amplitude vibration represented by a weakly binding phonon 21. In addition to the Stern-Gerlach spin, each electron of the weakly coupled Cooper pair at a ground bound state 20 moves in a helical motion in which the helix diameter is relatively large. By becoming bound, each electron of the weakly coupled Cooper pair at a ground bound state 20 has an increased energy, the gap between the free and the ground bound states represented by Δ. Thus, the weakly binding phonon 21 has an energy gap of 2Δ.

If a first free phonon 22, identical to the weakly binding phonon 21, collides with the Cooper pair at a ground bound state 20, the Cooper pair 20 could break apart releasing the phonon 21. The energy required to break the weakly coupled Cooper pair at a ground bound state 20 is relatively small, 10⁻³ eV. This energy is the equivalent to 2Δ.

However, the object of the stimulation process in the phonon maser is to provide the conditions for a population inversion. The implementation of this goal requires a coupling of each Cooper pair by as many phonons as possible, but never less than two.

FIG. 3B is a modified Feynman diagram showing a strong coupling of a Cooper pair. Take a multitude of strongly coupled Cooper pairs at a ground bound state 23 flowing in the Fermi sea of electrons within the superconductive gain medium executed in the high-temperature, Type II superconductor with a crystalline structure. Distances between the strongly bound Cooper pairs at a ground bound state 23 are greater than the distances between electrons in each pair. This condition of strong coupling is also called the Bose regime. The superconductive gain medium, in the Bose regime, provides for the Bose-Einstein Condensate (BEC). A second free phonon 24, bouncing between the highly reflective means and the partially reflective means in the BEC, rather than knocking out a strongly binding phonon 25 and separating the electrons of the strongly coupled Cooper pair at a ground bound state 23 (as it happens at the BCS regime), excites the pair, 23 raising it to the first excited state. The first free phonon, the second free phonon, the weakly binding phonon, and the strongly binding phonon are all identical, having the same binding strength of 10⁻³ eV. However, while the BSC regime is conducive to repulsion between the first free phonon and the weakly binding phonon, the Bose regime is conducive to constructive interference of lattice vibrations, the constructive interference resulting in the bundling of the second free phonon 24 and the strongly binding phonon 25.

Since high-temperature superconductivity is not yet well understood, many explanations of the strong coupling are offered. In the Discussion On Theory chapter, I mentioned a theory that suggests that the number of electrons in the Cooper pair is not limited to two. According to this theory, a Cooper pair in the excited state absorbs both the additional phonons and the additional electrons. It is no longer a pair but a molecule comprised of electrons and phonons where, in the BEC, the number of phonons expands quadratically, reflecting a quadratic expansion of the binding force, while the number of electrons always doubles the number of phonons. The method and the device of this invention remain feasible regardless of the true configuration of the Cooper pair (or Cooper molecule) in the excited state.

FIG. 3C is a modified Feynman diagram showing a Cooper pair after it absorbs the second free phonon. The result of the collision of the second free phonon with the strongly coupled Cooper pair at a ground bound state is a Cooper pair at the first excited state 26. Traditionally, this exited state is explained by a tighter helix of the spinning electrons and by an amplified vibration of the crystal lattice. However, according to the newer theory described on the previous page, the Cooper pair at the first excited state 26 comprises not two but four electrons. Thus, Cooper pair at the first excited state 26 is actually a molecule rather then a “pair”. In the future, I will be using the more traditional theory that limits the number of electrons in the Cooper pair to two.

Each electron of the Cooper pair of electrons at the first excited state 26 is characterized by an energy gap of 2Δ, and bound by a lattice vibration having an amplitude of twice the lattice vibration binding the strongly coupled Cooper pair at a ground bound state. This vibration is now represented by a bundle of two superposed binding phonons 27. Each phonon of the bundle of two superposed binding phonons 27 has an energy gap of 2Δ, with the total gap of 4Δ. When the number of the Cooper pairs of electrons at the first excited state 26, bound by a vibration with the energy gap of 4Δ, exceeds the number of the strongly coupled Cooper pairs at a ground bound state, bound by a vibration with the energy gap of 2Δ, a population inversion is achieved. In the condition of population inversion, a stream of phonons, resonating through the superconductive gain medium, produces more stimulated emission than stimulated absorption, thus this stream is amplified. If the system is in the condition of population inversion based on the two lowest energy levels of Cooper pairs, this system is only capable of a weak impulse phonon emission. The weak impulse phonon emission may be unsuitable for many practical applications.

One of the main goals of the proposed method and device of this invention is to provide a continuous emission of free phonons. Achieving this goal requires a continuous population inversion. In order to sustain the population inversion, it is necessary to further resonate the inverted population, more specifically, to elevate the Cooper pairs' binding energy by more than two energy levels without the pair's energy ever falling to the ground bound state.

Population inversion in the Bose regime is characterized by a spontaneous bundling of free phonons into bundles such as a bundle of two superposed free phonons 28. Because the vibration energy in Cooper pairs in the Bose regime could only rise quadratically, the Cooper pair at the first exited state could only absorb a vibration represented by the bundle of two superposed free phonons 28. Application of an energy greater than the gap of 4Δ to the Cooper pair of electrons at the first excited state 26 would break the pair 26 and release the bundle of two superposed free phonons 28.

FIG. 3D is a modified Feynman diagram showing the Cooper pair at the first exited state after this pair absorbs the bundle of two superposed free phonons.

Consider a collision of two identical bundles, a bundle of two superposed binding phonons with a bundle of two superposed free phonons. The result of constructive interference of lattice vibrations represented by the bundle of two superposed binding phonons and the bundle of two superposed free phonons, is a Cooper pair at the second exited state 29. The Cooper pair at the second exited state 29 is comprised of two electrons, each with the energy gap of 4Δ, and a bundle of four superposed binding phonons 30 with the lattice vibration energy gap of 8Δ. When the number of the Cooper pairs at the second exited state exceeds the number of the Cooper pairs at the first exited state (without the presence of the strongly-coupled Cooper pairs at a ground bound state), a coherent beam of phonons passing through the superconductive gain medium continuously produces more stimulated emission than stimulated absorption. The continuity of the stimulated emission is now assured.

In mathematical sense, the process of continued resonation of particles in the resonant cavity while pumping additional energy, bundles of superposed free phonons, colliding with bundles of superposed binding phonons, result in ever bigger bundles. In a physical sense, the constructing interference of vibrations leads to vibrations of ever-higher amplitude. The Cooper pairs are excited into progressively higher energy states with their energy gaps quadratically expanding to 16Δ, 32Δ, 64Δ, etc. The amplified vibrations, now represented by the bundles of superposed binding phonons, excite electrons while pulling them very close together. Per de Broglie, the helixes of the movement of individual electrons get tighter (while the wavelengths get longer), resulting in ever-greater densities of each Cooper pair. This, in-turn, allows the ever-greater packing of Cooper pairs while maintaining the strong coupling of the Bose regime. In other words, the number of Cooper pairs per same-diameter superconductor increases proportionally to the number of discrete amounts of positive energy binding each pair. (“An Analysis of Color Changes in Cuprate-based, Type II Superconductors Across Critical Temperature”, William Ames, TEKNOS 2005, pp. 36-40).

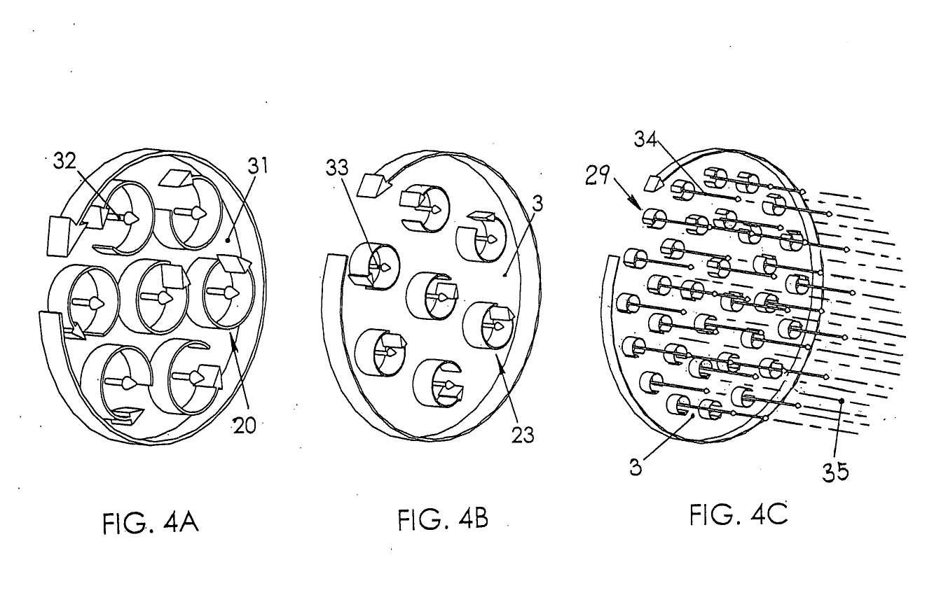

FIG. 4A is a diagram of a cross-section of a low-temperature superconductor 31 (Type I conventional superconductor) showing a multitude of the weakly coupled Cooper pairs at a ground bound state 20 in the weak coupling condition of the BCS regime. Note the relatively close distances between pairs. The short length of the vibration force vector of a weakly coupled Cooper pair at a ground bound state 32 represents the energy gap of 2Δ. The weakness of coupling is thought to be caused by pair-to-pair interference. The use of low-temperature superconductor 31 would not promote signal amplification process. FIG. 4A is included to illustrate the difference between the weak coupling condition of the BCS regime and a strong coupling condition of the Bose regime.

FIG. 4B is a diagram of a cross-section of the superconductive gain medium 3, showing a multitude of the strongly coupled Cooper pairs at a ground bound state 23 in the strong coupling condition of the Bose regime before the population inversion. Note the relatively great distances between the pairs in the high-temperature Type II superconductor of the superconductive gain medium 3. The short length of a vibration force vector of strongly coupled Cooper pair at a ground bound state 33 represents an energy gap of 2Δ.

FIG. 4C is a diagram of a cross-section of the superconductive gain medium 3 showing a multitude of Cooper pairs at the second excited state 29 after the population inversion. Note the small diameters of Cooper pairs and relatively great distances between the pairs reflecting the continued state of the Bose regime. The substantial length of the vibration force vector of Cooper pair at the second excited state 34 reflects the energy gap of 8Δ.

The method of the current invention requires resonating the inverted population until a new threshold is reached such that the bundles of superposed free phonons break through the partially reflective means. The power of the phonon maser depends on the size of the bundles of superposed free phonons that break through the partially reflective means in a coherent and collimated beam.

Consider a population inversion into an eighth excited state in which Cooper pairs are bound by a high-amplitude vibration represented by a bundle of 256 superposed phonons. The partially reflective means are calibrated to allow only the bundles of 256 superposed free phonons to break through. A coherent beam of high-amplitude vibrations, each with an energy of 25.6 eV, breaks through the partially reflective means and enters the vacuum as a coherent beam of bundles of superposed guest phonons 35.

The phonon maser of this invention could maintain the population inversion continuously with relatively few Cooper pairs breaking up. However, if an application of voltage provides the Cooper pairs with an energy larger than an energy gap of 512Δ, this energy would break the Cooper pairs into high-energy electrons while releasing in a single impulse the high-amplitude vibrations, represented by the bundles of 256 superposed free phonons. This is why the phonon maser of the current invention may provide, on demand, a continuous or an impulse emission of the coherent beam of bundles of superposed guest phonons 35.

Compare the coherent beam of bundles of superposed guest phonons 35 with a beam reportedly generated by the 1992 Podkletnov machine. Each released charge of the phonon maser has the power of 256 Podkletnov machine charges. The charge density is much greater because the Cooper pairs in the superconductive gain medium of the phonon maser would be packed 256 times more densely than the Cooper pairs in the Podkletnov machine. Moreover, the superconductive gain medium of the preferred embodiment of the phonon maser is over 20 times thicker than Podkletnov's disk. The result is the coherent beam of bundles of superposed guest phonons 35 of much greater intensity than Podkletnov's beam. The gravitational effect along the line of propagation of the coherent beam of bundles of superposed guest phonons 35 is proportionally greater. With preferred embodiment of the phonon maser, with a proper cooling, the population inversion into twentieth or even fiftieth excited state is possible. With the other embodiments, the maximum-size bundle of superposed phonons of over 3.01×10²³ phonons, or half of the Avogadro number, is achievable.

Compare a phonon maser beam comprised of the maximum-size bundles of superposed phonons with the reported single-phonon beam of the Podkletnov machine or the single-phonon field of the de Matos/Tajmar machine. Each phonon generated by these two machines has an energy charge of only 2.43×10⁻³⁴ Joules. The maximum-size bundles generated by the phonon maser (projected from the original data provided by Shoulders & Shoulders), could each carry a relatively high energy charge of about 7.31^{-1l} Joules. Thus, the phonon maser generates a local gravity or repulsive force many times stronger than the Earth's gravity while the beam of the Podkletnov machine and the field of the de Matos/Tajmar machine caused barely-detectable gravity changes, these changes equivalent to a tiny fraction of the Earth's gravity. Small in its cross section, the phonon maser beam is also coherent, collimated, and all-penetrating.

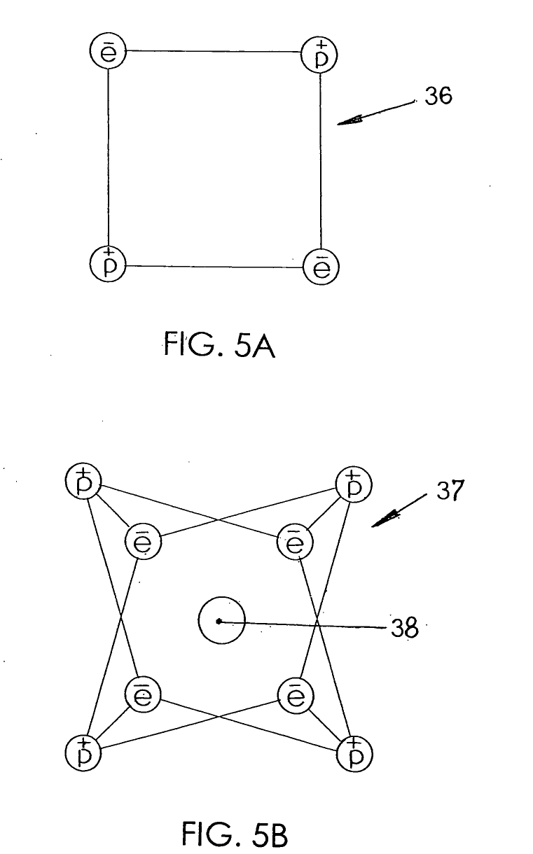

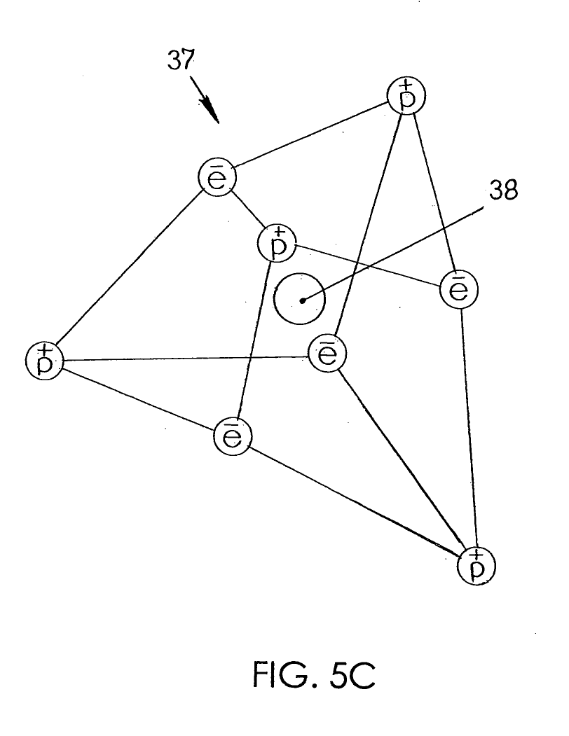

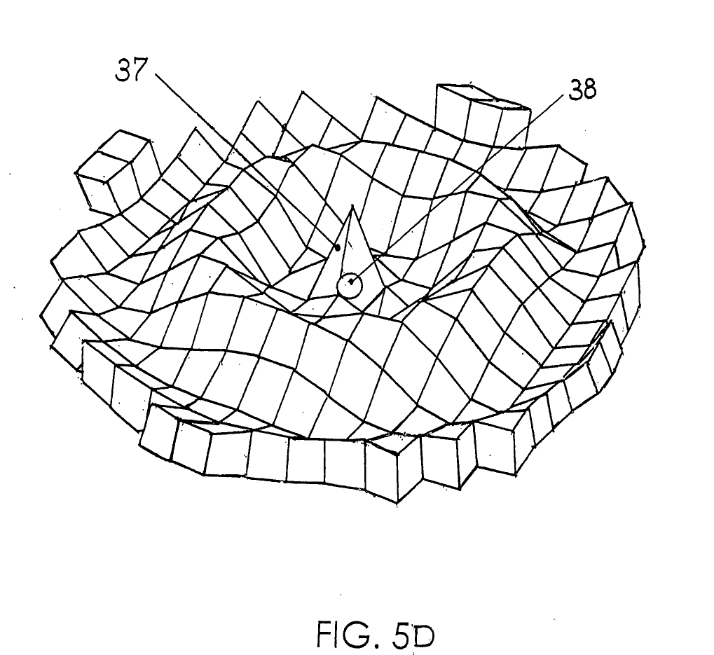

FIG. 5A is a schematic diagram of the side of an undistorted cubic unit cell 36 of the vacuum crystal lattice. The undistorted cubic unit cell 36 is shown to be a simple cube similar to that in ionic alkali halide salts. Per Simhony, this structure of the unit cell is representative of the crystal lattice of the vacuum. The markings usually reserved for real (massive) electrons and positrons also apply if these particles of the vacuum crystal lattice are virtual (energy).

FIG. 5B is a schematic diagram of the side of a distorted cubic unit cell 37. In the “Discussion” section on pages 8, 9, and 10, I offered a theory on the possible way in which the gravitational energy of the vacuum could be artificially affected. According to this theory, a vibration represented by a bundle of superposed guest phonons 38, having a positive charge, causes a momentary deformation of the distorted cubic unit cell 37 by pulling the negatively-charged virtual electrons, and repelling the positively-charged virtual positrons.

Because of the energy provided by cosmic radiation, the crystal lattice of the vacuum naturally vibrates. Depending on the stage of the cycle of the natural vibration at the moment of entry, the bundle of superposed guest phonons 38 may amplify, dampen, stop, or completely invert the natural vibration of the distorted cubic unit cell 37. As the coherent beam of bundles of superposed guest phonons (not shown on FIG. 5B) propagates forward, the artificially-created ripples of waves, caused by the distortions of the individual unit cells, propagate through the crystal lattice of the vacuum interfering with the naturally-occurring waves. The next FIG. 5C shows these ripples.

FIG. 5C is a three dimensional schematic diagram of the distorted cubic unit cell 37. As in FIG. 5B, in FIG. 5C the bundle of superposed guest phonons 38 is shown centrally entering the distorted cubic unit cell 37. The only difference between FIG. 5B and FIG. 5C is that the distorted cubic unit cell 37 in the FIG. 5B is shown as two-dimensional, and in FIG. 5C it is three-dimensional. There is a possibility that the crystal lattice of the vacuum is comprised of unit cells that are not cubic. For example, in the U.S. Pat. No. 6,353,311 B1, John P. Brainard et al. show a Universal Particle Flux Field that appears to have hexagonal-sided unit cells. The unit cells of the crystal lattice of the vacuum may be shaped as rhombohedrons, tetrahedrons, octahedrons, etc., all expected to react to the bundle of superposed guest phonons in a way that would make this invention feasible.

As the bundle of superposed guest phonons propagates forward, the artificially-created ripples of waves, caused by the distortions of the individual unit cells, propagate through the crystal lattice of the vacuum interfering with the naturally-occurring waves. The speed of propagation of these naturally-occurring waves equals the speed of propagation of the bundle of superposed guest phonons, both speeds matching the speed of light. If the bundle of superposed guest phonons is characterized by a vibration matching the natural vibration of the unit cell of the crystal lattice of the vacuum, then the frequency of the artificially-created ripples of waves coincides with the frequency of the naturally-occurring waves of the crystal lattice of the vacuum. Therefore, the bundle of superposed guest phonons characterized by a vibration matching the natural vibration of the unit cell in frequency and in phase, amplifies this natural vibration. This is the case of constructive interference resulting in a temporary local increase in the gravitational energy of the vacuum.

A bundle of superposed guest anti-phonons (not shown), matching the natural vibration in frequency but with the wave phase-shifted 180 degrees, dampens the natural vibration because of the destructive interference of the waves. This destructive interference results in the temporary local reduction in the gravitational energy of the vacuum. In the case when the amplitude of the wave represented by the bundle of superposed guest anti-phonons equals the amplitude of the naturally-occurring wave, a complete stop of vibration results in a complete, temporary and local elimination of the gravity effect. In the case when the amplitude of the wave represented by the bundle of superposed guest anti-phonons exceeds the amplitude of the naturally-occurring wave, a temporary and local 180-degree reversal in the direction of vibration of the crystal lattice of the vacuum results in a 180-degree reversal in the direction of the propagation of the gravitational energy.

In the method for vibration energy amplification by stimulated emission of radiation, a step of calibrating the phonon maser is required. This step provides for the emission of the bundles of superposed guest phonons (or anti-phonons) having a frequency matching the frequency of natural vibration of the crystal vacuum lattice. This added step assures that the coherent beam of bundles of superposed guest phonons (or anti-phonons) results in changes in amplitude of the natural vibration of the crystal vacuum lattice.

FIG. 5D is a three-dimensional schematic diagram of the distorted cubic unit cell 37 centrally positioned within a single cell-thick slice of the crystal lattice of the vacuum. This slice comprises a plurality of cubic cells most affected by the bundle of superposed guest phonons 38. As in FIG. 5B and FIG. 5C, in FIG. 5D the bundle of superposed guest phonons 38 is shown centrally entering the distorted cubic unit cell 37. Ripples of waves, caused by the propagation of the coherent beam of bundles of superposed guest phonons 38, affect the most those unit cells that are the closest to the distorted cubic unit cell 37, and diminish with distance. These ripples change the local environment, affecting gravity, inertia, speed of light, forces of electromagnetic interaction, energies, and radiations. This is why the phonon maser capable of creating and emitting the bundles of guest phonons would play an important role in the future development of science and industry.

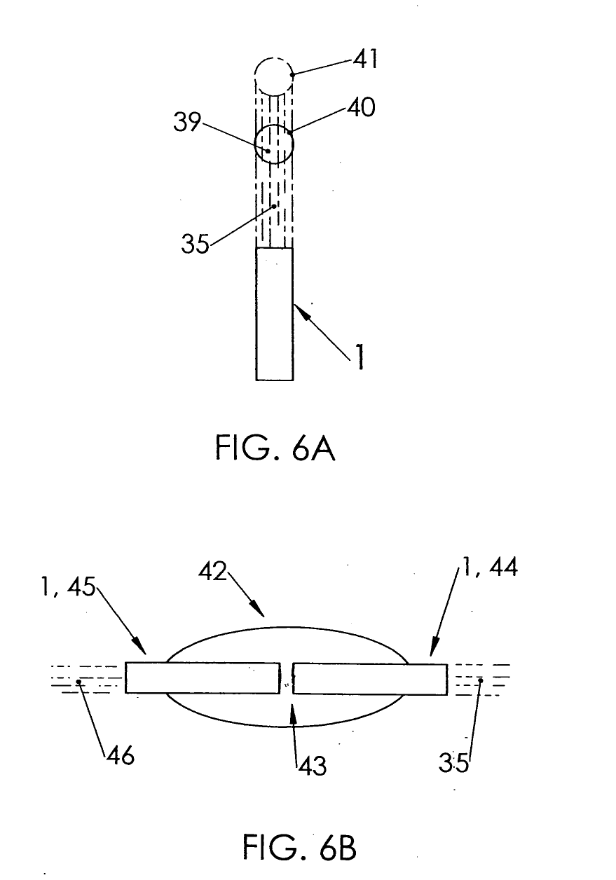

FIG. 6A is a diagram illustrating an example of practical application for the phonon maser 1 and the method for vibration energy amplification by stimulated emission of radiation. In this example, after a target 39 is identified, the phonon maser 1, aimed at the target 39, emits the coherent beam of bundles of superposed guest phonons 35 moving the target 39 from an initial location to a desired location 41.

This example of practical application represents a number of specific uses for the phonon maser. For example, the coherent beam of bundles of superposed guest phonons, emitted by the phonon maser, would move the orbiting spaceship from a wrong orbit to a proper orbit.

In another use, the phonon maser, by projecting the coherent beam of bundles of superposed guest phonons at an airplane or a space vehicle, launches the airplane or the space vehicle from a launching strip or a launching pad.

In yet another use, a sector of a flywheel is affected by the coherent beam of bundles of superposed guest phonons emitted by the phonon maser located at a distance, urging the sector to rotate. If the flywheel is a part of an electrical generator, the energy is transferred wirelessly.

In still another use of the phonon maser, a sensor of a receiver is triggered by the coherent beam of bundles of superposed guest phonons emitted in impulses by the phonon maser located at another distance. In the process of a wireless communication transmission, the receiver registers each of these impulses as an information bit. The impulses could be transmitted to a receiver located anywhere on Earth through the Earth's mass. Thus, one transmitting station comprising one or more phonon masers could replace a system of communication satellites.

In the last use, two or more of the phonon masers are aimed at a foreign or harm-causing body such as a blockage in the artery or a kidney stone. While each of the coherent beams of bundles of superposed guest phonons may not be powerful enough to affect the patient's surrounding tissues, the combination of the beams crisscrossed at the foreign or harm-causing body, create a force powerful enough to pull or push the body from a location where the foreign or harm-causing body causes harm to a location where it is harmless.

FIG. 6B is a diagram that illustrates another example of practical application for the phonon maser and the method for vibration energy amplification by stimulated emission of radiation, specifically the application for vehicle propulsion. A spaceship 42 has a spaceship engine 43 comprising back-to-back at least two of the phonon masers disposed longitudinally to each other: a first phonon maser 44 and a second phonon maser 45. Electromagnetic energy is pumped into the superconductive gain mediums of the phonon masers. However, while the vibrations of the crystal lattice structures of the superconductive gain mediums of the first phonon maser 44 and the second phonon maser 45 coincide in frequency, their waves are 180 degrees phase-shifted. If the vibration quanta in the first phonon maser 44 are expressed as phonons, than the second phonon maser 45 generates anti-phonons.

The steps of the propulsion method are identical to the above-described method of vibration energy amplification by stimulated emission of radiation. The result of bundling of binding phonons is bundles of superposed binding phonons in the first phonon maser, and the result of bundling of binding anti-phonons are bundles of superposed binding anti-phonons in the second phonon maser. Likewise, the result of bundling of free phonons is bundles of superposed free phonons in the first phonon maser 44, and the result of bundling of free anti-phonons is bundles of superposed free anti-phonons in the second phonon maser 45. The bundles of superposed free phonons break through the partially reflective means of the first phonon maser as the coherent beam of bundles of superposed guest phonons 35, and the bundles of superposed free anti-phonons break through the partially reflective means of the second phonon maser as a coherent beam of bundles of superposed guest anti-phonons 46.

The spaceship engine 43 projects the coherent beam of bundles of superposed guest phonons 35 in one direction, and the coherent beam of bundles of superposed guest anti-phonons 46 in the opposite direction. By creating repulsion (and expanding spacetime) behind the spaceship 42 and creating gravity (and contracting spacetime) in front of the spaceship, the spaceship engine 43 would generate high-speed propulsion.

The new theory of gravitophonon generation and emission offered here, just as the theory of a crystal lattice of the vacuum of Menahem Simhony (“The Epola Space”, M. Simhony, 1990, Jerusalem, Israel, 160 pp, “The Story of Matter and Space”, M. Simhony, 1999, Jerusalem, Israel, 70 pp.) are yet to become the part of mainstream science. Much more generalized theories on the gravitomagnetic energy emissions effecting density of the vacuum and zero-point fluctuations are currently accepted. These theories have been empirically proven by Casimir, Tajmar-de Matos, and other researchers. A skeptical reader is welcome to substitute “phonon emission” with “gravitomagnetic energy emission” and “vibration of the crystal lattice of the vacuum” with “zero point fluctuations”. The novelty, the performance, and the usefulness of the device of this invention are in no way jeopardized if the herein suggested new theories happen to be imprecisely or even wrongly defined. In fact, the experiments with the phonon maser will allow scientists to learn a great deal more about the gravitational effects such as gravity and repulsion.

I claim:

1. A phonon maser, comprising:
a resonant cavity;
a superconductive gain medium, the superconductive gain medium disposed in said resonant cavity,
and
pumping means, the pumping means and said superconductive gain medium disposed rotatably to each other.

2. The phonon maser of claim 1, further including a support structure, the support structure holding said superconductive gain medium and said pumping means in a position providing for their relative rotation.

3. The phonon maser of claim 2 wherein said pumping means are at least one solenoid coil.

4. The phonon maser of claim 2 wherein said pumping means are at least one electro-magnet.

5. The phonon maser of claim 2 wherein said superconductive gain medium is a substantially elongated superconductor cooled to a temperature providing superconductivity in said superconductive gain medium.

6. The phonon maser of claim 5 wherein said superconductive gain medium is a crystalline ceramic superconductor.

7. The phonon maser of claim 6 wherein said superconductive gain medium are pre-aligned fused crystals.

8. The phonon maser of claim 6 wherein said superconductive gain medium is a polycrystalline.

9. The phonon maser of claim 6 wherein said superconductive gain medium is a single crystal.

10. The phonon maser of claim 5 wherein said resonant cavity is comprised of:
highly reflective means, the highly reflective means disposed proximate to one end of said superconductive gain medium, and
partially reflective means, the partially reflective means disposed proximate to an opposite end of said superconductive gain medium, there a space provided between said highly reflective means and said partially reflective means defining a void, the void enveloping said superconductive gain medium.

11. The phonon maser of claim 10 wherein said highly reflective means is a highly polished surface of said superconductive gain medium on said end of said medium.

12. The phonon maser of claim 10 wherein said partially reflective means is a partially polished surface of said superconductive gain medium on said opposite end of said medium.

13. The phonon maser of claim 10 wherein said highly reflective means further include a highly reflective material layer, the highly reflective material layer disposed on said highly polished surface of said superconductive gain medium.

14. The phonon maser of claim 10 wherein said partially reflective means further include a partially reflective material layer, the partially reflective material layer disposed on said partially polished surface of said superconductive gain medium.

15. The phonon maser of claim 10 wherein said highly reflective means further include a highly reflective superconductor, the highly reflective superconductor disposed proximate to said highly reflective material layer longitudinally to said superconductive gain medium.

16. The phonon maser of claim 10 wherein said partially reflective means further include a partially reflective superconductor, the partially reflective superconductor disposed proximate to said partially reflective material layer longitudinally to said superconductive gain medium.

17. The phonon maser of claim 16 wherein said partially reflective means are cooled to another temperature lower than said temperature of said superconductive gain medium.

18. The phonon maser of claim 17 wherein said highly reflective means are cooled to a still another temperature lower than said another temperature of said partially reflective means.

19. The phonon maser of claim 10 wherein materials for said highly reflective means and said partially reflective means are provided in which the speed of particle propagation is slower than the speed of particle propagation in the material of said superconductive gain medium.

20. The phonon maser of claim 19 wherein the material for said highly reflective means is provided in which the speed of particle propagation is slower than the speed of particle propagation in the material of said partially reflective means.

21. The phonon maser of claim 10 wherein said resonant cavity further comprises:
an energy source,
a highly reflective end electrode, the highly reflective end electrode disposed on said highly reflective means, said highly reflective end electrode connectively disposed to said energy source,
and
a partially reflective end electrode, the partially reflective end electrode disposed on said partially reflective means, said partially reflective end electrode connectively disposed to said energy source.

22. The phonon maser of claim 10 further includes a back-beam shield, the back-beam shield disposed on said support structure orthogonally to said superconductive gain medium on a longitudinal axis extending from said highly reflective means.

23. The phonon maser of claim 10 wherein said superconductive gain medium is rotatably disposed at an electromagnetic flux-transmittable distance from said pumping means.

24. The phonon maser of claim 23 further including at least one superconductive gain medium electric motor, the superconductive gain medium electric motor connectively disposed to said superconductive gain medium, whereby said superconductive gain medium electric motor assists the rotation of said superconductive gain medium against said pumping means.

25. The phonon maser of claim 10 wherein said pumping means are rotatably disposed at the electromagnetic flux-transmittable distance to said superconductive gain medium.

26. The phonon maser of claim 25 further including at least one pumping means electric motor, the pumping means electric motor disposed connectively to said pumping means, whereby said pumping means electric motor assists the rotation of said pumping means against said superconductive gain medium.

27. A method for vibration energy amplification by stimulated emission of radiation comprising the steps of:
providing a phonon maser, the phonon maser comprised of a resonant cavity, a superconductive gain medium, and pumping means; the resonant cavity comprised of highly reflective means and partially reflective means,
pumping electromagnetic energy into said superconductive gain medium thereby providing for a Fermi sea of free electrons in said medium,
vibrating a crystal lattice of said superconductive gain medium by way of the spin of free electrons, the vibration of said crystal lattice being phonons,
binding free electrons into Cooper pairs with phonons providing the binding energy,
reflecting free electrons, free phonons, and Cooper pairs proximate to end surfaces of said superconductive gain medium, back into said medium by way of said highly reflective means and said partially reflective means,
bundling of binding phonons into bundles of superposed binding phonons,
bundling of free phonons into bundles of superposed free phonons,
resonating said bundles of superposed free phonons propagating between said highly reflective means and said partially reflective means until a threshold is reached wherein said bundles produce more stimulated emission than stimulated absorption, thereby providing for a population inversion,
resonating the inverted population until a new threshold is reached where said bundles of superposed free phonons break through said partially reflective means,
and
emitting said bundles of superposed free phonons into ambient space as bundles of superposed guest phonons in a coherent beam of bundles of superposed guest phonons,
whereby said coherent beam of bundles of superposed guest phonons changes properties of the ambient space including its gravitational energy.

28. The method for vibration energy amplification by stimulated emission of radiation of claim 27 wherein said population inversion in said superconductive gain medium provides for the increase of the Cooper pairs' binding energy by more than two energy levels without ever falling to a ground bound state,
whereby providing for a continuous population inversion,
whereby providing for a continuous emission of said coherent beam of bundles of superposed guest phonons.

29. The method for vibration energy amplification by stimulated emission of radiation of claim 27 wherein said step of resonating said inverted population further includes the step of passing the energy greater than the gap to excited Cooper pairs,
whereby breaking the excited Cooper pairs into high-energy electrons and said bundles of superposed free phonons,
whereby providing for an impulsed population inversion,
whereby providing for an impulsed emission of said coherent beam of bundles of superposed guest phonons.

30. The method for vibration energy amplification by stimulated emission of radiation of claim 27 further including the step of calibrating said phonon maser prior to said step of pumping electromagnetic energy, said calibrating providing for emitting of said bundles of superposed guest phonons having a frequency matching the frequency of natural vibration of crystal vacuum lattice,
whereby locally modulating an amplitude of natural vibration of said crystal vacuum lattice,
whereby changing properties of ambient space including its gravitational energy.

31. The method for vibration energy amplification by stimulated emission of radiation of claim 27 further comprising the additional steps taken prior to said step of pumping electromagnetic energy into said superconductive gain medium:
identifying a target that needs to be moved from an initial location to a desired location, and
aiming said phonon maser at said target,
whereby locally modulating the amplitude of vibration of said crystal vacuum lattice in the direction of said target,
whereby affecting said target with the gravitational energy,
whereby urging said target to move from said initial location to said desired location.

32. A method of propulsion by vibration energy amplification comprising the following steps:
providing a spaceship engine, the spaceship engine comprising a plurality of phonon masers including a first phonon maser and a second phonon maser disposed back-to-back longitudinally to each other; the first phonon maser and the second phonon maser each including a resonant cavity, a superconductive gain medium, and pumping means; the resonant cavity including highly reflective means and partially reflective means,
pumping electromagnetic energy into said superconductive gain mediums of said phonon masers,
vibrating a crystal lattice of said superconductive gain medium by way of the spin of free electrons, the vibration of said crystal lattice being phonons in said first phonon maser
and simultaneously
vibrating a crystal lattice of said superconductive gain medium by way of the spin of free electrons, the vibration of said crystal lattice being anti-phonons in said second phonon maser,
binding free electrons into Cooper pairs with phonons providing the binding energy in said first phonon maser
and simultaneously
binding free electrons into Cooper pairs with anti-phonons phonons providing the binding energy in said second phonon maser,
reflecting free electrons, free phonons, and Cooper pairs, all proximate to end surfaces of said superconductive gain medium, back into said medium by way of said highly reflective means and said partially reflective means in said first phonon maser
and simultaneously
reflecting free electrons, free anti-phonons, and Cooper pairs, all proximate to end surfaces of said superconductive gain medium, back into said medium by way of said highly reflective means and said partially reflective means in said second phonon maser,
bundling of binding phonons into bundles of superposed binding phonons in said first phonon maser
and simultaneously
bundling of binding anti-phonons into bundles of superposed binding anti-phonons in said second phonon maser,
bundling of free phonons into bundles of superposed free phonons in said first phonon maser
and simultaneously
bundling of free anti-phonons into bundles of superposed free anti-phonons in said second phonon maser,
resonating said bundles of superposed free phonons, propagating between said highly reflective means and said partially reflective means, until a threshold is reached where said bundles of superposed free phonons produce more stimulated emission than stimulated absorption in said first phonon maser
and simultaneously
resonating said bundles of superposed free anti-phonons, propagating between said highly reflective means and said partially reflective means, until a threshold is reached where said bundles of superposed free anti-phonons produce more stimulated emission than stimulated absorption in said second phonon maser,
resonating the inverted population until a new threshold is reached where said bundles of superposed free phonons break through said partially reflective means of said first phonon maser
and simultaneously
resonating the inverted population until a new threshold is reached where said bundles of superposed free anti-phonons break through said partially reflective means of said second phonon maser,
emitting said bundles of superposed free phonons into ambient space in the form of a coherent beam of bundles of superposed guest phonons in one direction by said first phonon maser
and simultaneously
emitting said bundles of superposed free anti-phonons into ambient space in the form of a coherent beam of bundles of superposed guest anti-phonons in the opposite direction by said second phonon maser,
whereby said coherent beam of bundles of superposed guest phonons creates gravity in front of said spaceship engine by contracting space and diluting time,
and simultaneously
said coherent beam of bundles of superposed guest anti-phonons creates repulsion behind said spaceship engine by diluting space and contracting time,
whereby said spaceship engine generates high-speed propulsion.
